(19) United States
(12) Patent Application Publication
(10) Pub. No.: US 2005/0272250 A1
(43) Pub. Date: Dec. 8, 2005

(54) Method of forming self-aligned contact and method of manufacturing semiconductor memory device by using the same

(76) Inventors: Cheol-Ju Yun, Gyeonggi-do (KR); Tae-Young Chung, Gyeonggi-do (KR); In-Ho Nam, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/147,953

(22) Filed: Jun. 7, 2005

(30) Foreign Application Priority Data
Jun. 7, 2004 (KR) 2004-41311

(51) Int. Cl. H01L 21/44; H01L 21/48; H01L 21/50; H01L 21/4763

(52) U.S. Cl. 438/622; 438/637

(57) ABSTRACT

In an embodiment a method of forming self-aligned contacts in a semiconductor memory device includes: forming conductive stacks of conductive layers on a semiconductor substrate; forming insulating spacer layers on sidewalls of the conductive stacks; forming an insulating layer; forming a capping insulating layer covering portions of the insulating layer; and forming conductive pads that fill the contact holes to contact the semiconductor substrate. The capping insulating layer has a function of a buffer, so an etched amount of mask layers insulating the conductive layers is minimized, and a probability of a short circuit between capacitor electrodes and the conductive stacks is greatly reduced.

### BACKGROUND OF THE INVENTION

This application claims the priority of Korean Patent Application No. 2004-41311, filed on Jun. 7, 2004, in the Korean Intellectual Property Office, the disclosure of which is incorporated herein in its entirety by reference.

1. Field of the invention

Embodiments of the present invention relate to a method of manufacturing a semiconductor memory device, and more particularly, to a method of forming a self-aligned contact and a method of manufacturing a semiconductor memory device by using the method of the self-aligned contact.

2. Description of Related Art

Recently, the resolution of lithography processes has improved, so that line width and line pitch in a semiconductor memory device can be drastically reduced. However, alignment technique cannot keep abreast with the resolution of the lithography. Therefore, it is important to minimize misalignment while manufacturing the semiconductor memory device. In particular, in a semiconductor memory device having capacitors, such as a dynamic random access memory (DRAM) device, bit lines are formed, and then the capacitors are formed with an effort to increase their effective area. In this case, after the bit lines are formed, it is necessary to form buried contact (BC) pads for electrically connecting source and drain regions of transistors to lower electrodes, i.e., storage electrodes, of the capacitors. To form the BC pads, long and deep contact holes are formed with a high aspect ratio. However, it is very difficult to ensure a sufficient alignment margin for the lithography process for forming these contact holes. Therefore, there has recently been a widely used method of forming a self-aligned contact. In this method, the contact holes are formed by covering lower conductive layers with insulating layers and performing an etching process using the lower conductive layers and the insulating layers as aligning masks.

FIGS. 1 and 2 are layout views of a conventional method of forming self-aligned contacts in a semiconductor memory device and a conventional method of manufacturing the semiconductor memory device by using the method of forming the self-aligned contacts. FIGS. 3 and 4 are cross sectional views taken along lines A-A′ and B-B′ of FIG. 1, respectively. FIGS. 5 and 6 are cross sectional views taken along lines A-A′ and B-B′ of FIG. 2, respectively. FIGS. 7 to 9 are cross sectional views taken along line A-A′ of FIG. 2.

First, referring to FIGS. 1, 3, and 4, gate stacks 145 are formed to extend in a transverse direction as a stripe on a semiconductor substrate 100 having active regions 120 defined by an isolation layer 110. Next, conductive pads 141 and 142 are formed to pass through a first insulating layer 131 between the gate stacks 145. The conductive pads 141 are buried contact (BC) pads 141 for connecting the active regions 120 to lower electrodes of capacitors, and the conductive pads 142 are direct contact (DC) pads 142 for connecting the active regions 120 to bit lines. Next, a second insulating layer 132 is formed on the gate stacks 145, the first insulating layer 131, and the conductive pads 141 and 142. After the second insulating layer 132 is formed, DC contact plugs 144 are formed to pass through the second insulating layer 132 and contact with the DC pads 142. Next, bit line stacks 150 are formed to extend transverse to the gate stock direction on the DC contact plugs 144. Each of the bit line stacks 150 is formed by sequentially stacking a barrier layer 151, a metal layer 152, and a mask layer 153. Next, bit line spacer layers 160 are formed on the sidewalls of the bit line stacks 150. Next, gaps between the bit line stacks 150 are filled with a third insulating layer 133.

Next, referring to FIGS. 2, 5, and 6, conductive layers 171 made of, for example, polysilicon, and photoresist layer patterns 172 are formed in this order on the bit line stacks 150 and the third insulating layer 133. The photoresist layer patterns 172 have a shape of a line. The photoresist layer patterns 172 are parallel to the gate stacks 145 to intersect the bit line stacks 150. In particular, the photoresist layer patterns 172 have openings, so that some portions of the conductive layers 171 disposed over the DC pads 142 are covered and other portions of the conductive layers 171 disposed over the BC pads 141 are exposed. In some examples, the process for forming the conductive layers 171 may be omitted. Although the conductive layers 171 are not shown in FIG. 2, the conductive layers 171 are considered to be disposed as in the following description.

Subsequently, referring to FIG. 7, an etching process is performed by using the photoresist layer patterns 172 as masks, so that the exposed portions of the conductive layers 171 are removed. Next, the photoresist layer patterns 172 are removed. Next, another etching process is performed by using the remaining portions of the conductive layers 171 as masks, so that the third insulating layer 133 and the second insulating layer 132 are removed in this order. As a result, BC contact holes 180 are formed to expose top surfaces of the BC pads 141. During the processes for removing the third insulating layer 133 and the second insulating layer 132, some portions of the mask layer 152 of the bit line stacks 150 and some portions of the bit line spacer layers 160, which are not covered with the conductive layers 171, are removed. As a result, the thickness of the mask layer 152 is reduced by a predetermined thickness d1, and the thickness of the bit line spacer layers 160 is reduced by a predetermined thickness d2.

Next, referring to FIG. 8, a conductive material layer is formed to fill the BC contact holes 180. Next, an etching process is performed on the conductive material layer to obtain BC contact plugs 143 which are separated from each other. The performed etching process is an over-etching process for removing a certain thickness d1′ of the mask layers 153 of the bit line stacks 150. Since the thickness of the mask layers 153 not covered with the conductive layers 171 is reduced by the predetermined thickness d1 and the thickness of the mask layers 152 covered with the conductive layers 171 are not changed, there are step differences, so that the conductive material may remain at the corners of the interface between the mask layer 153 with reduced thickness and the mask layer 153 with unchanged thickness. Therefore, the aforementioned etching process needs to remove the conductive material remaining at the comers. As a result, the thickness of the mask layers 153 is further reduced.

Next, referring to FIG. 9, etching stopper layers 134 and mold oxide layers 135 are stacked in this order on the BC contact plugs 143 and the bit line stacks 150. Next, a photoresist layer pattern (not shown) having openings is formed on the mold oxide layers 135 to expose some portions of the mold oxide layers 135. Next, an etching process using the photoresist layer pattern as a mask is performed to sequentially remove the exposed portions of the mold oxide layers 135 and the etching stopper layers 134. During this etching process, some portions of the mask layer 153 of the bit line stacks 150 are also etched, so that the thickness of the mask layers 153 not covered with the mold oxide layers 135 and the etching stopper layers 134 are further reduced. Next, a lower electrode layer 190 of the capacitor is formed to contact with the top surface of the BC contact plugs 143 exposed in the aforementioned etching process. Next, although not shown in FIG. 9, a dielectric layer and an upper electrode layer of the capacitor are formed in this order on the lower electrode layer 190 by using a typical capacitor formation process.

According to the conventional method of forming self-aligned contacts and the conventional method of manufacturing semiconductor memory device using the method of forming the self-aligned contacts, the thickness of the mask layers 153 of the bit line stacks 150 and the thickness of the bit line spacer layers 160 are reduced by the etching process used to form the BC contact holes 180 (see FIG. 7), and the thickness of the mask layers 153 is further reduced by the etching process used to isolate the BC contact plugs 143 (see FIG. 8) and the etching process on the mold oxide layers 135 and the etching stopper layers 134 used to form the lower electrode layer 190. As a result, there is a high probability of a short circuit occurring between the lower electrode layer 190 of the capacitor or the BC contact plugs 143 and the metal layers 152 of the bit line stacks 150. Therefore, reliability of the semiconductor memory device may be reduced. In particular, the probability of the short circuit occurring is very high between the members indicated by arrows a, b, and c in FIG. 9.

### SUMMARY

Embodiment's of the present invention provide a method of forming a self-aligned contact capable of reducing the probability of a short circuit occurring between metal layers of the bit line stacks and a lower electrode layer or a buried contact (BC) plug of a capacitor by preventing a reduction of thickness of mask layers of the bit line stacks.

Embodiments of the present invention also provide a semiconductor memory device by using the method of the self-aligned contact.

According to an embodiment of the present invention, there is provided a method of forming self-aligned contacts in a semiconductor memory device, comprising: forming conductive stacks by stacking a conductive layer and an insulating mask layer in this order on a semiconductor substrate; forming insulating spacer layers on sidewalls of the conductive stacks; forming an insulating layer filling gaps between the conductive stacks; forming mask layer patterns to expose some portions of the insulating layer; removing the exposed portions of the insulating layer by performing an etching process using the mask layer patterns as etching masks; forming a capping insulating layer covering the substantially remaining portions of the insulating layer, the insulating spacer layers, and the conductive stacks; forming contact holes to expose some portions of the semiconductor substrate by sequentially removing exposed portions of the capping insulating layer and the remaining portions of the insulating layer; and forming conductive pads filling the contact holes to contact the semiconductor substrate.

According to another embodiment of the present invention, there is provided a method of forming self-aligned contacts in a semiconductor memory device, comprising: forming bit line stacks on a lower insulating layer covering conductive pads; forming bit line spacer layers on sidewalls of the bit line stacks; forming an upper insulating layer filling gaps between the bit line spacer layers; forming mask layer patterns to expose some portions of the upper insulating layer; removing the exposed portions of the upper insulating layer by performing an etching process using the mask layer patterns as etching masks to remain a predetermined thickness of the upper insulating layer over the lower insulating layer; forming a capping insulating layer covering the substantially remaining portions of the upper insulating layer, the bit line spacer layers, and the bit line stacks; forming contact holes to expose the conductive pads by sequentially removing exposed portions of the capping insulating layer, the remaining upper insulating layer, and the lower insulating layer; and forming conductive plugs filling the contact holes to contact the conductive pads.

### BRIEF DESCRIPTION OF THE DRAWINGS

The above and other features and advantages of the present invention will become more apparent by describing in detail exemplary embodiments thereof with reference to the attached drawings.

FIGS. 1 and 2 are layout views for explaining a conventional method of forming self-aligned contacts in a semiconductor memory device and a conventional method of manufacturing the semiconductor memory device by using the method of forming the self-aligned contacts.

FIG. 3 is a cross sectional view taken along line A-A′ of FIG. 1.

FIG. 4 is a cross sectional view taken along line B-B′ of FIG. 1.

FIG. 5 is a cross sectional view taken along line A-A′ of FIG. 2.

FIG. 8 is a cross sectional view taken along line B-B′ of FIG. 2.

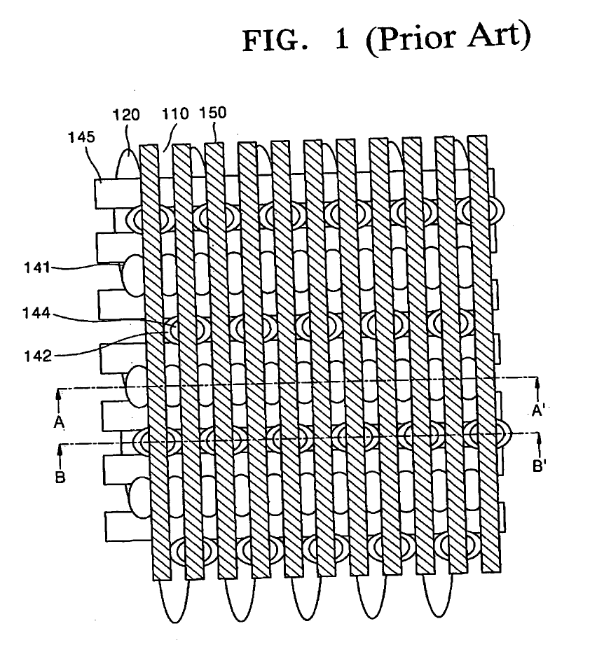

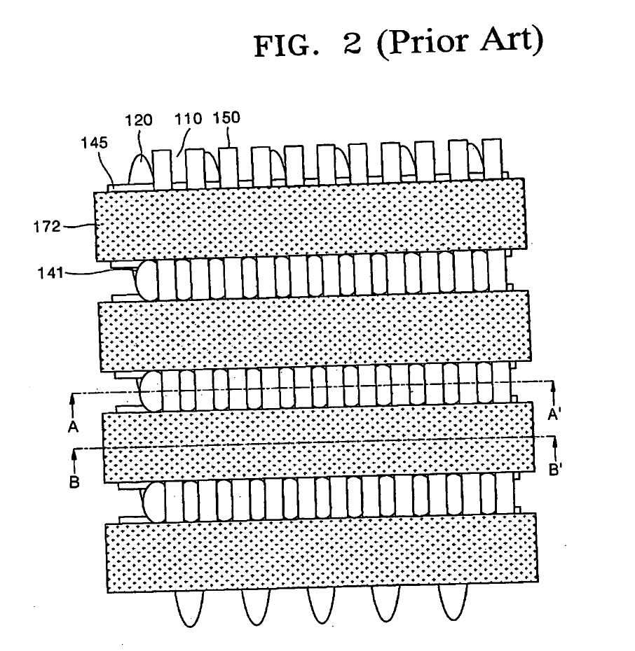

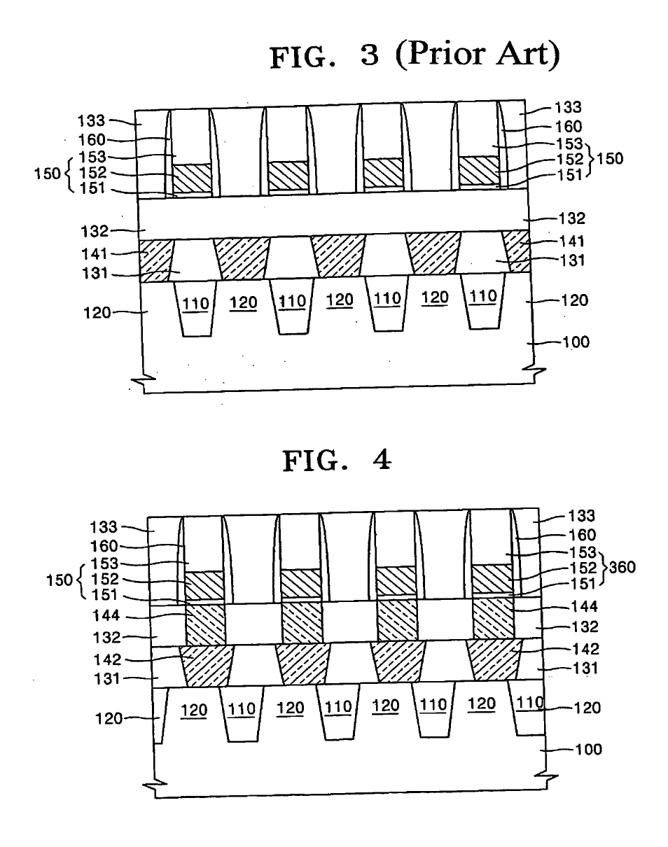

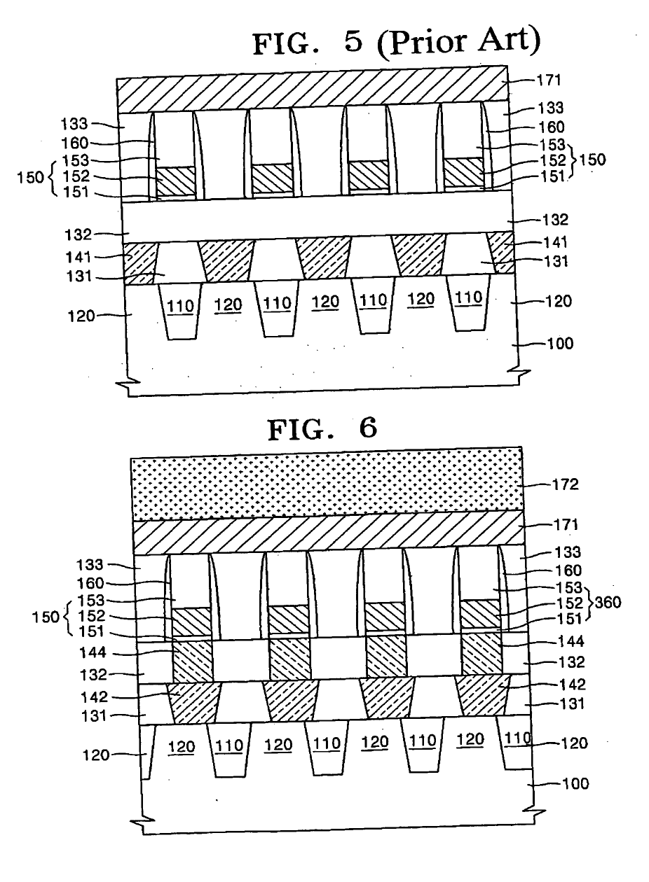

FIGS. 7 to 9 are cross sectional views taken along line A-A′ of FIG. 2 for explaining processes of FIG. 2.

FIGS. 10 to 29 are views for explaining a method of forming self-aligned contacts in a semiconductor memory device and a method of manufacturing a semiconductor memory device using the method of forming the self-aligned contacts according to an embodiment of the present invention.

FIGS. 30 to 40 are cross sectional views for explaining a method of forming self-aligned contacts in a semiconductor memory device and a method of manufacturing a semiconductor memory device using the method of forming the self-aligned contacts according to another embodiment of the present invention.

### DETAILED DESCRIPTION

Embodiments of the present invention and operational advantages thereof can be fully understood by referring to the accompanying drawings and explanations thereof.

Exemplary embodiments of the present invention will be described with reference to the accompanying drawings to explain the present invention in detail. In the drawings, the same reference numerals indicate the same elements.

For example, the present invention can be adapted to a DRAM device in a gate stack level as well as a bit line level. However, only the bit level will be described to avoid a redundancy of description.

FIGS. 10 to 29 are views for explaining a method of forming self-aligned contacts in a semiconductor memory device and a method of manufacturing a semiconductor memory device using the method of forming the self-aligned contacts according to an embodiment of the present invention. More specifically, FIGS. 17 and 18 are cross sectional views taken along lines A-A′ and B-B′ of FIG. 12, respectively. FIGS. 19 and 20 are cross sectional views taken along lines A-A′ and B-B′ of FIG. 14, respectively. FIGS. 21 is a cross sectional view taken along a line B-B′ of FIG. 15. FIGS. 22 and 23 are cross sectional views taken along lines A-A′ and B-B′ of FIG. 15, respectively. FIGS. 24 to 27 are cross sectional views taken along lines A-A′ of FIG. 15. FIGS. 28 and 29 are cross sectional views taken along lines A-A′ of FIG. 16.

Referring to FIGS. 10 to 12, 17 and 18, an isolation layer 310 is formed on a semiconductor substrate 300, for example, a silicon substrate, to define active regions 320 where devices are formed. The isolation layer 310 has a form of a trench. Alternatively, the isolation layer 310 may have a form of a local-oxidation-of-silicon (LOCOS). Next, gate stacks 350 are formed on the semiconductor substrate 300. The gate stacks 350 extend in a stripe across a row of active regions 320, as shown in FIG. 12. After the gate stacks 350 are formed, gate spacer layers (not shown) are formed on the side surfaces of the gate stacks 350. As a result, some portions of the active regions 320 are covered with the gate stacks 350, and other portions of the active regions 320 are exposed.

Next, conductive pads 341 and 342 are formed to pass through a first insulating layer 331 between the gate stacks 350. The conductive pads 341 are buried contact (BC) pads 341 for connecting the active regions 320 to lower electrodes of capacitors, and the conductive pads 342 are direct contact (DC) pads 342 for connecting the active regions 320 to bit lines. The conductive pads 341 and 342 are formed as follows. Firstly, the first insulating layer 331 is formed on the semiconductor substrate 300 in which the gate stacks 350 and the gate spacer layers (not shown) are formed. Predetermined mask layer patterns (not shown) are formed on the first insulating layer 331. Next, some portions of the active regions 320 of the semiconductor substrate 300 are exposed by performing an etching process using the mask layer patterns and the gate spacer layers as etching masks. Next, conductive layers are formed to contact the exposed portions of the active regions 320. Next, a planarization process is performed to separate the conductive layers. As a result, the conductive pads 341 and 342 are obtained.

Next, referring to FIGS. 13, 14, 19, and 20, a second insulating layer 332 is formed on the gate stacks 350 and the conductive pads 341 and 342. Some portions of the second insulating layer 332 are removed by performing an etching process using predetermined mask layer patterns as etching masks to form contact holes exposing only the DC pads 342 out of the conductive pads 341 and 342. Next, DC contact plugs 344 filling the contact holes with a conductive material are formed to contact the DC pads 342. Next, bit line stacks 360 are formed on the semiconductor substrate 300 in which the second insulating layer 332 and the DC contact plugs 344 are formed. The bit line stacks 360 extend in the longitudinal direction as stripes to intersect the gate stacks 350, as shown in FIG. 14. Each of the bit line stacks 360 are formed by sequentially stacking a barrier layer 361, a metal layer 362, and a mask layer 363. Typically, the mask layers 363 are made of silicon nitride SiN. Next, bit line spacer layers 370 are formed on sidewalls of the bit line stacks 360 by performing a sidewall spacer forming process. Typically, the bit line spacer layers 370 are also made of silicon nitride SiN. Next, gaps between the bit line stacks 360 are filled with a third insulating layer 333.

Referring to FIGS. 15 and 21, photoresist layer patterns 382 are formed as mask layer patterns on the bit line stacks 360 and the third insulating layer 333. The photoresist layer patterns 382 extend in the longitudinal direction as a stripe, so that the photoresist layer patterns 382 intersect the bit line stacks 360 and partially overlap the gate stacks 350 in parallel. In particular, the photoresist layer patterns 382 have openings covering the DC contact plugs 344 and exposing some portions of the third insulating layer 333 where the BC pads 341 are formed. A structure shown in the cross section taken along the line A-A′ of FIG. 15 is the same as the structure shown in the cross section view of FIG. 19.

Alternatively, as shown in FIGS. 22 and 23, conductive layers 381 made of polysilicon may first be formed. The photoresist layer patterns 382 are formed as mask layer patterns on the conductive layers 381. In this case, after the conductive layers 381 and the photoresist layer patterns 382 are sequentially stacked, photoresist layers are patterned to cover the DC contact plugs 344 and expose some portions of the third insulating layer 333 where the BC pads 341 are formed.

Referring to FIG. 24, the exposed portions of the third insulating layer 333 are removed by performing an etching process. Here, the etching process may be a dry or wet etching process. In some cases, the etching process may be a combination of the dry and wet etching processes.

First, description is made about the aforementioned case where the conductive layers 381 are not formed. By performing the etching process using the photoresist layer patterns 382 as the etching masks, the exposed portions of the third insulating layer 333 are removed by a predetermined thickness. Here, the level of top surface of the remaining third insulating layer 333′ is arranged to be higher than at least the level L1 of the top surfaces of the metal layers 362 of the bit line stacks 360.

Next, description is made about the aforementioned alternative case where the conductive layers 381 are formed. By performing the etching process using the photoresist layer patterns 382 as the etching masks, all the exposed portions of the conductive layers 381 are removed. As a result, conductive layer patterns 381 are formed under the photoresist layer patterns 382. Next, the photoresist layer patterns 382 are removed, so that the conductive layer patterns 381 are exposed. Next, some portions of the third insulating layer 333 are removed by performing an etching process using the conductive layer patterns 381 as etching masks. In this case, the level of the top surface of the remaining third insulating layer 333′ is also arranged to be higher than at least the level L1 of the top surface of the of the metal layers 362 of the bit line stacks 360. Since the etching process is performed to remove only the predetermined thickness of the third insulating layer 333, it is possible to perform the etching process with a sufficiently high etching selection ratio in comparison with a conventional etching process.

Referring to FIG. 25, after some portions of the third insulating layer 333 are removed, a capping spacer layer 334 is formed on the remaining third insulating layer 333′, the bit line stacks 360, and the bit line spacer layers 370. The capping spacer layer 334 is made of, for example, silicon oxide which has low step coverage by using a chemical vapor deposition (CVD) method. As a result, the thickness d_{b} of the capping spacer layer 334 over the remaining third insulating layer 333′ is thicker than the thickness dₜ of the capping spacer layer 334 over the bit line stacks 360. Alternatively, the capping spacer layer 334 may be made of silicon nitride which has low step coverage by using a physical vapor deposition (PVD) method or a low-pressure chemical vapor deposition (LP-CVD) method.

Referring to FIG. 26, a dry etching process is performed on the surface of the resulting product, in which the capping spacer layer 334 is formed, to sequentially remove the capping insulating layer 334, the remaining third insulating layer 333′ and the exposed portions of the second insulating layer 332. Here, the dry etching process is performed with a relatively low etching selection ratio in comparison with the etching process of removing some portions of the third insulating layer 333. As a result of the dry etching process, BC contact holes 391 exposing top surfaces of the BC pads 341 are obtained. During the dry etching process, the capping spacer layer 334 on mask layers 363 of the bit line stacks 360 has a function of a buffer for the mask layers 363. Therefore, the thickness d₃ of the etched portions of the mask layers 363 are not large. In addition, the capping spacer layer 334 on the bit line spacer layers 370 has a function of a buffer for the bit line spacer layers 370, so that the reduction of the thickness of the bit line spacer layers 370 can be suppressed during the dry etching process.

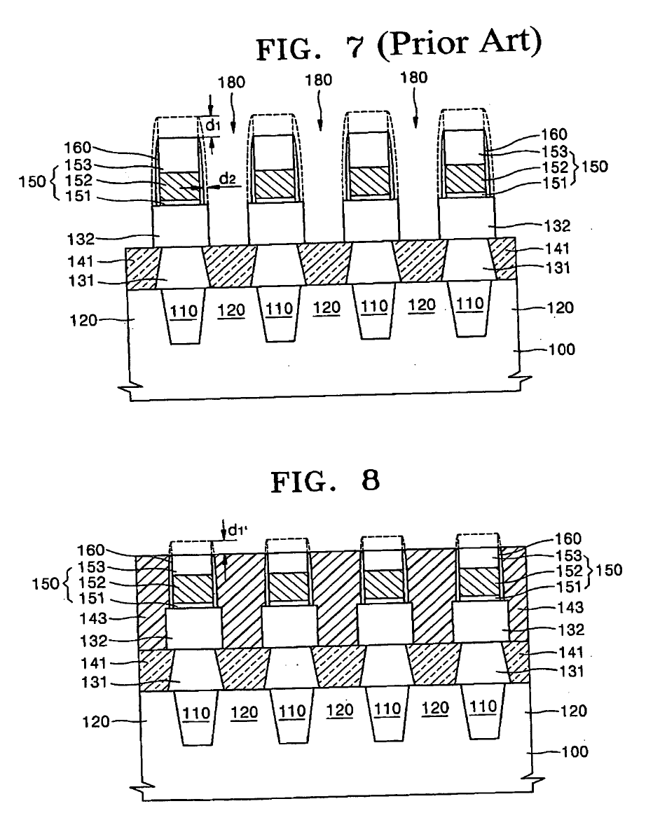

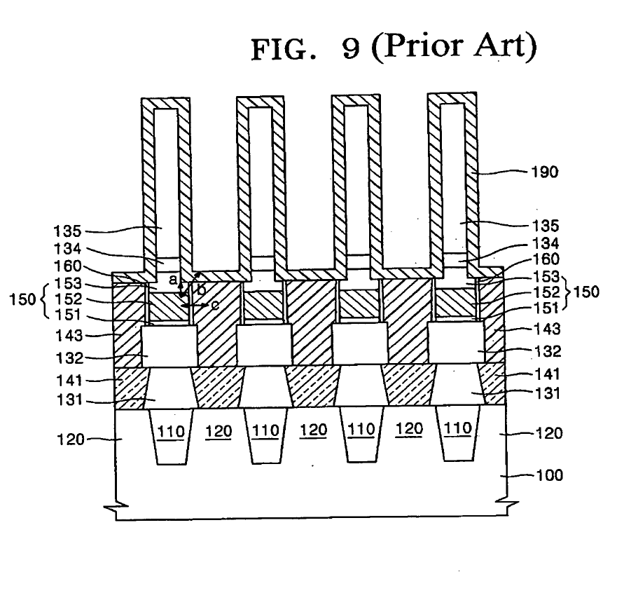

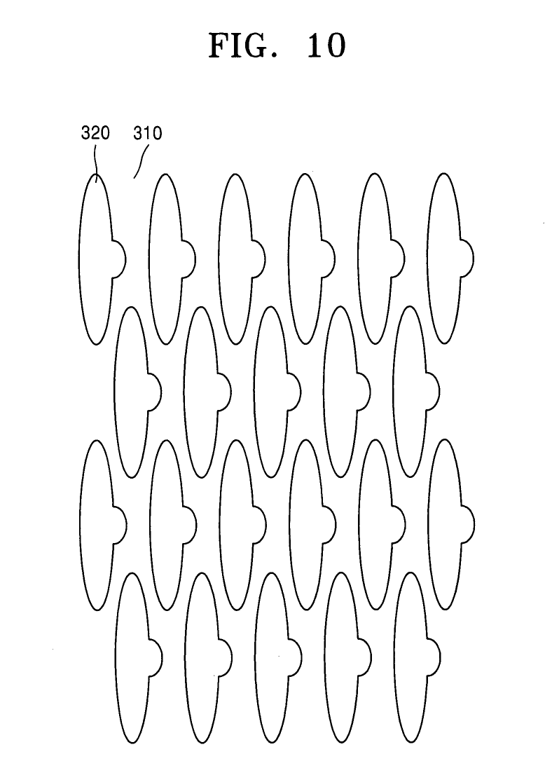

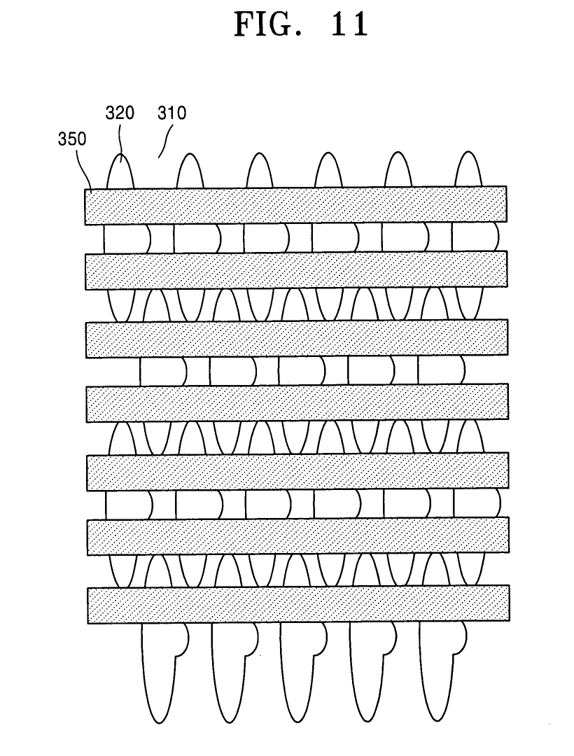

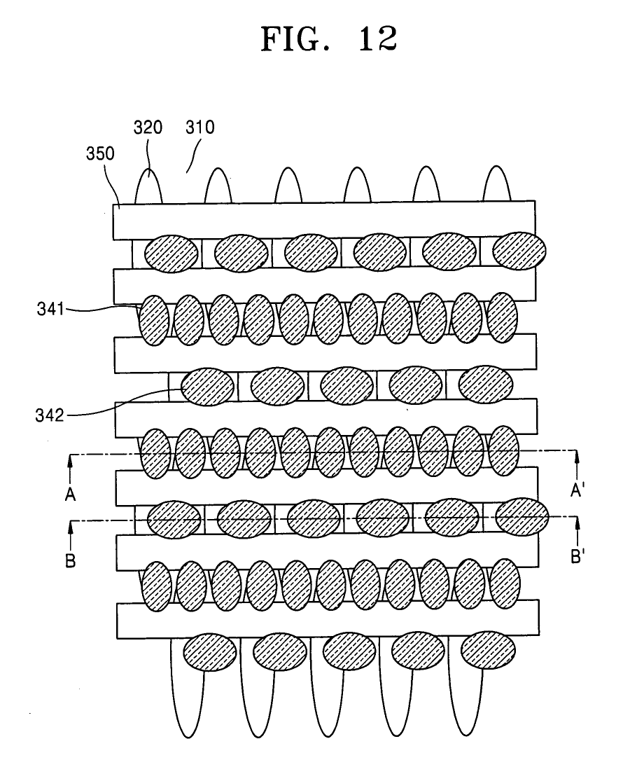

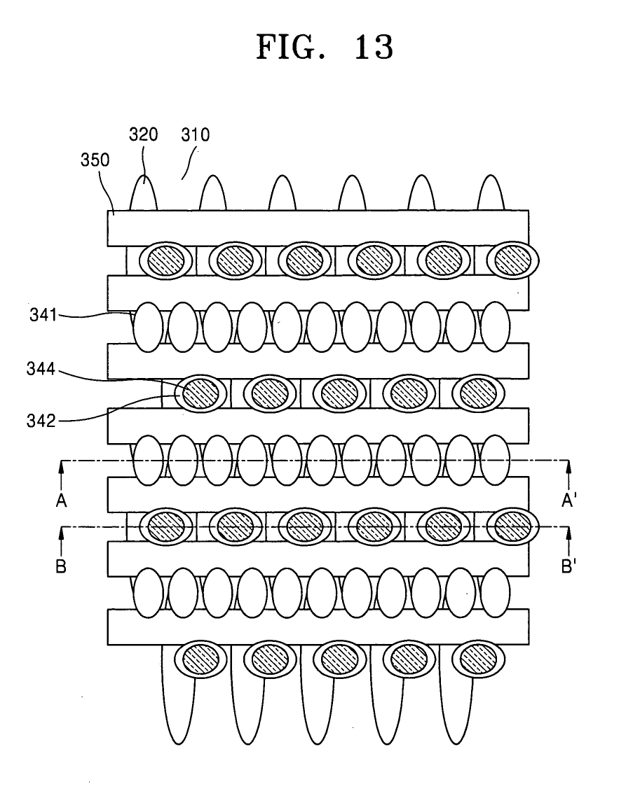

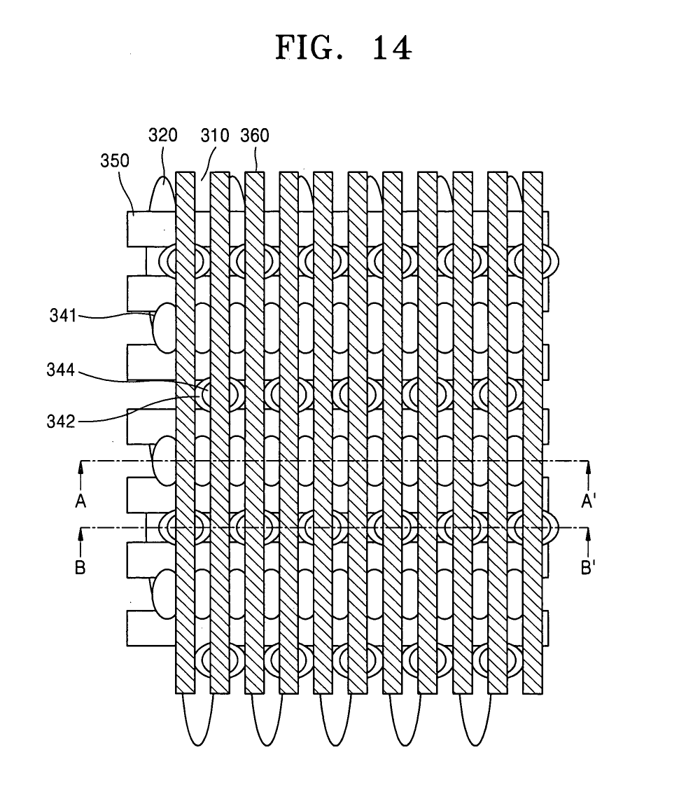

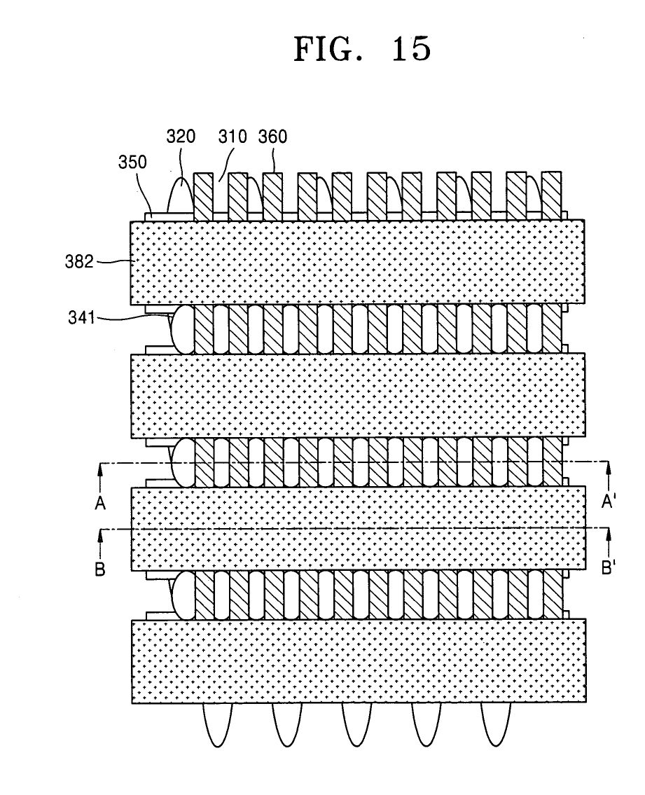

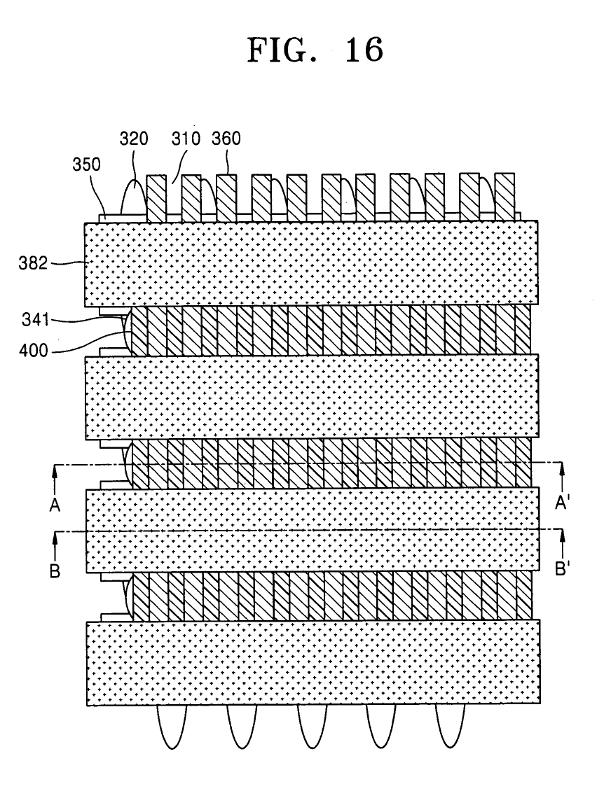

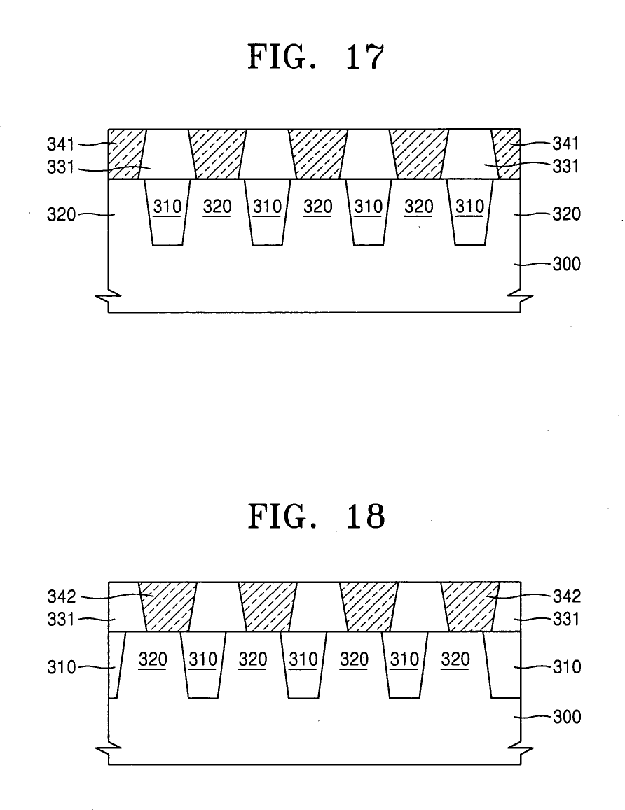

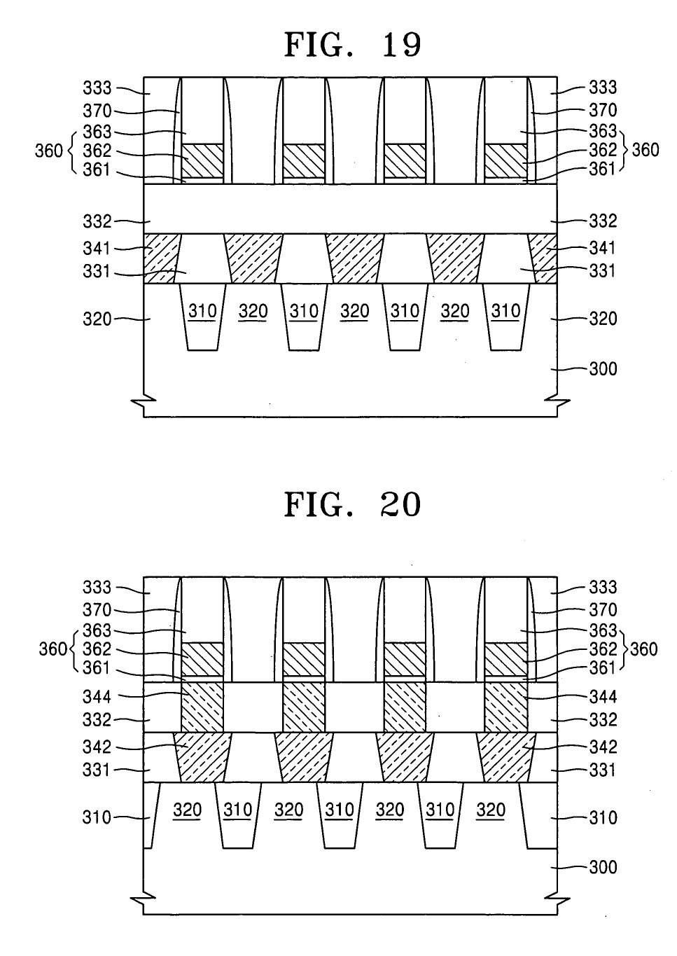

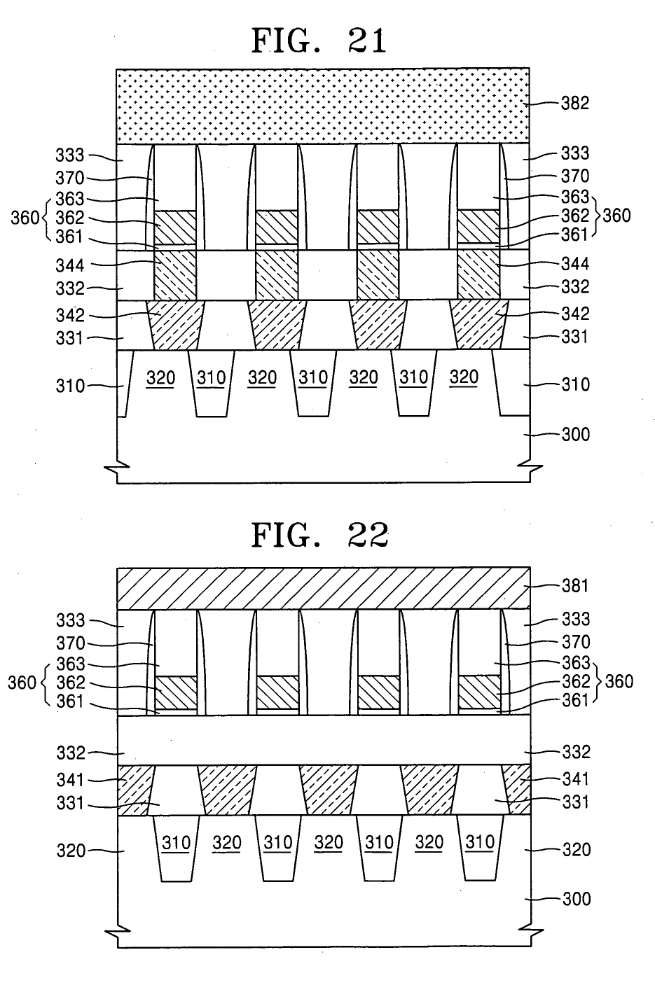

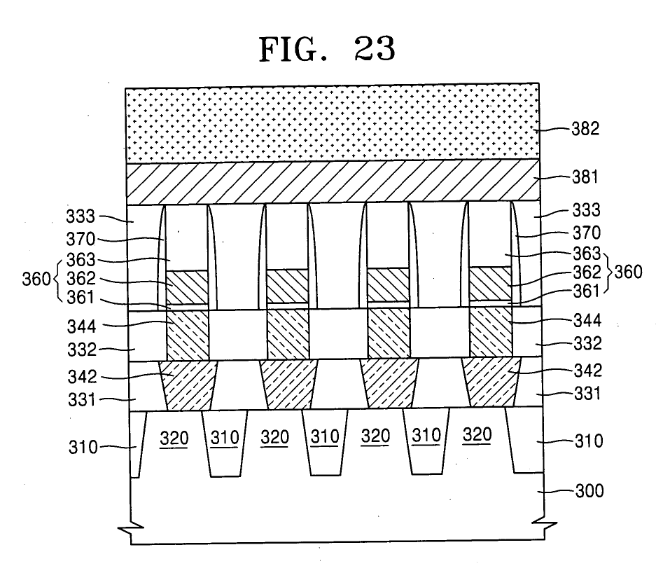

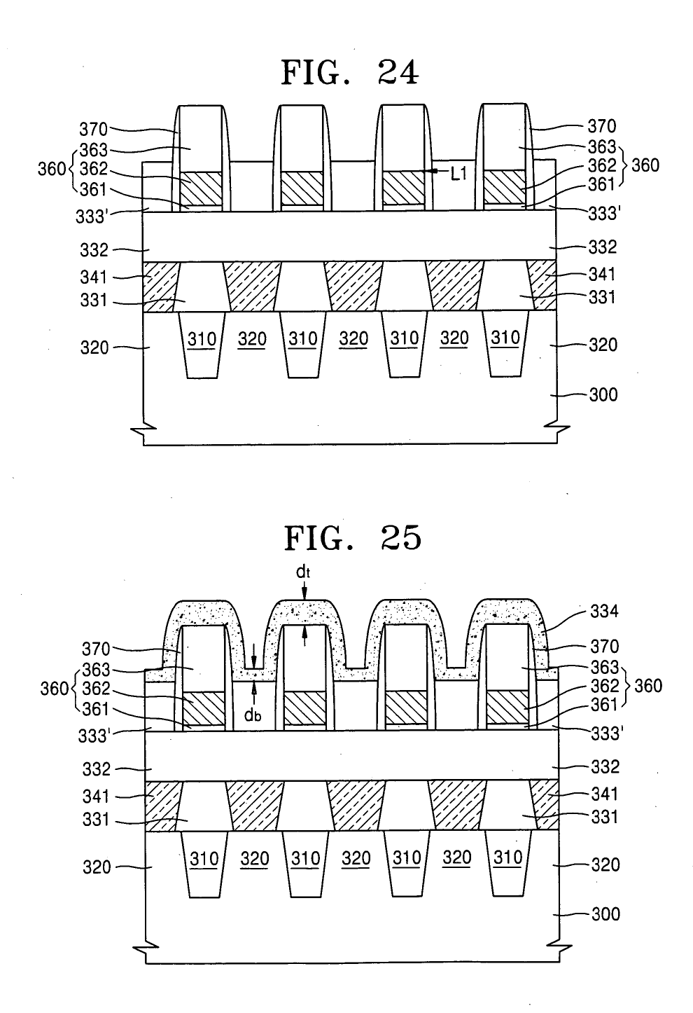

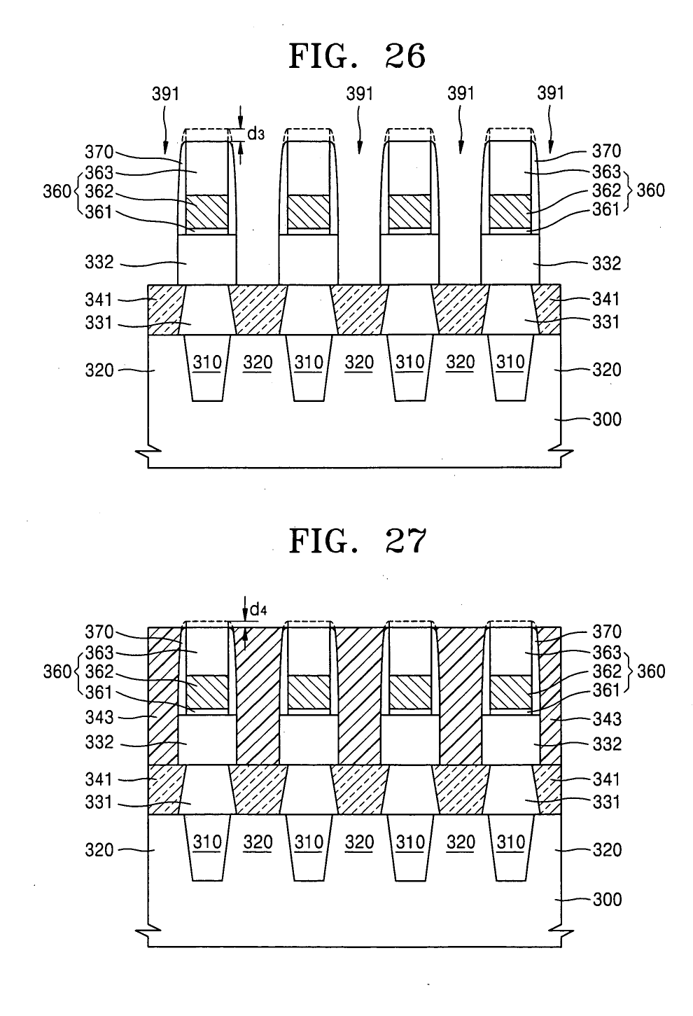

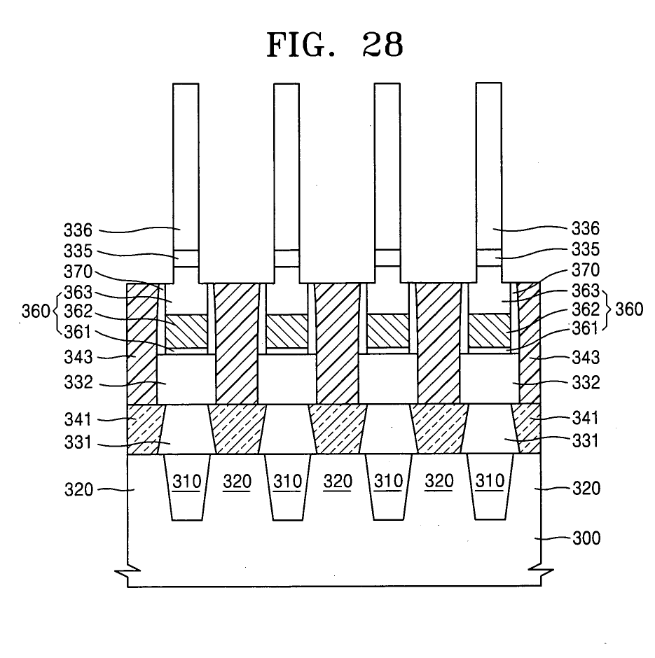

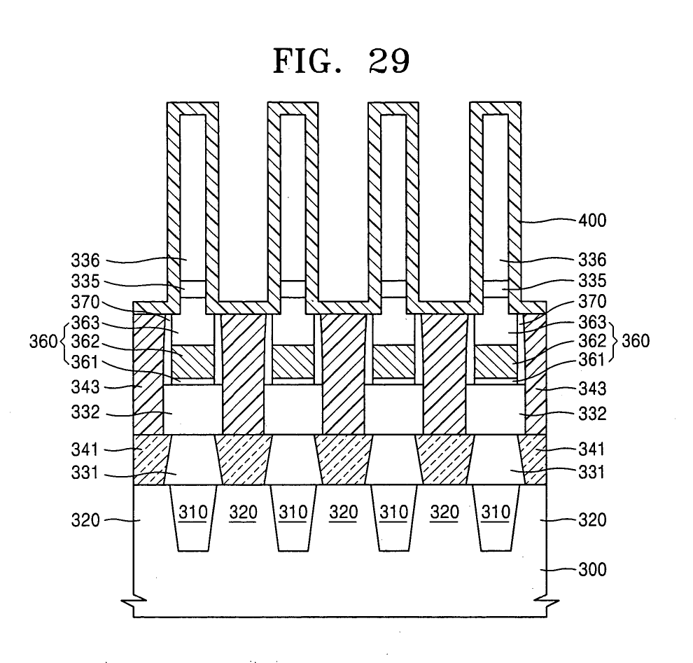

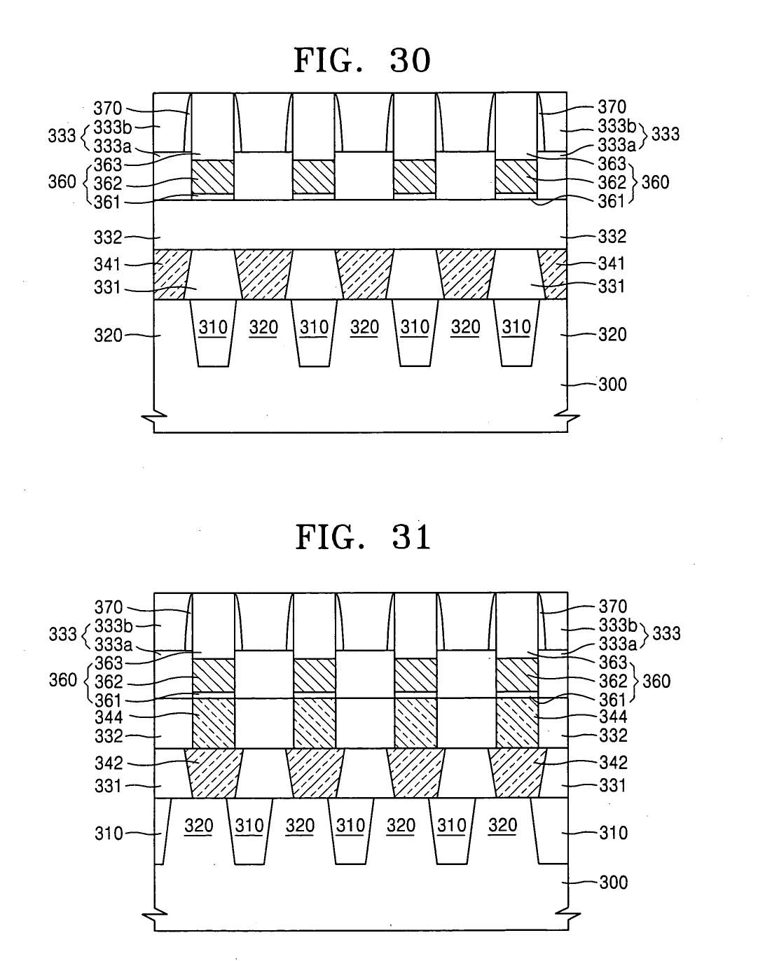

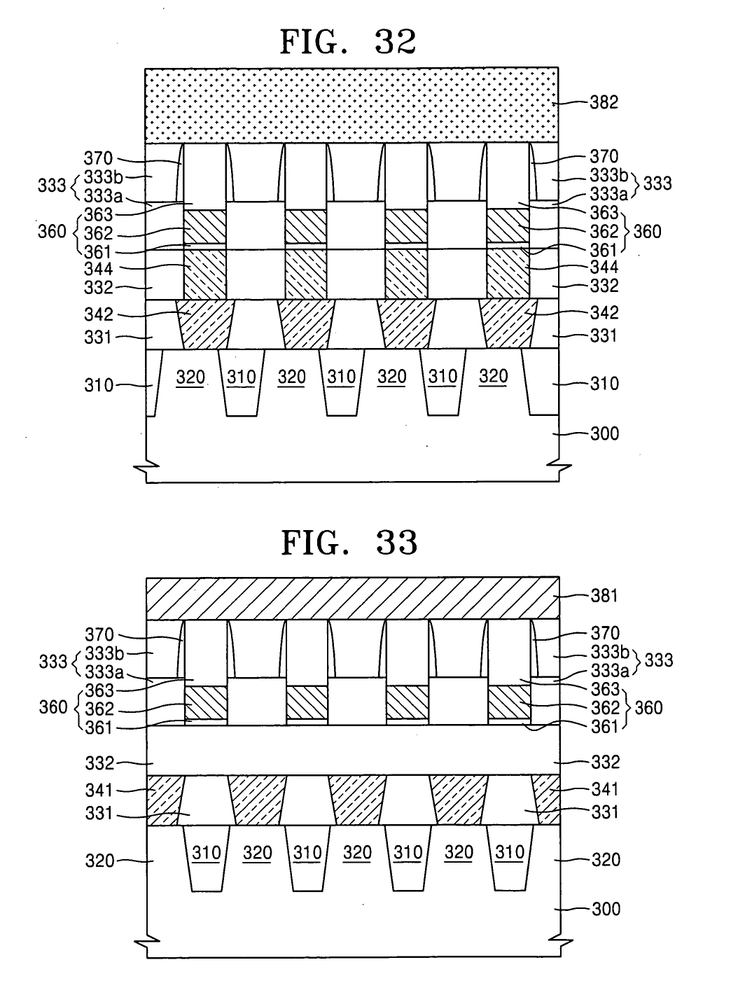

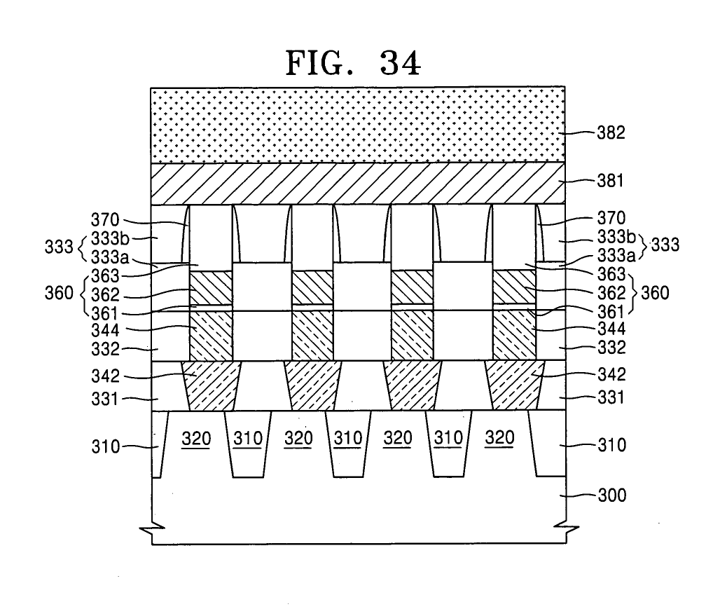

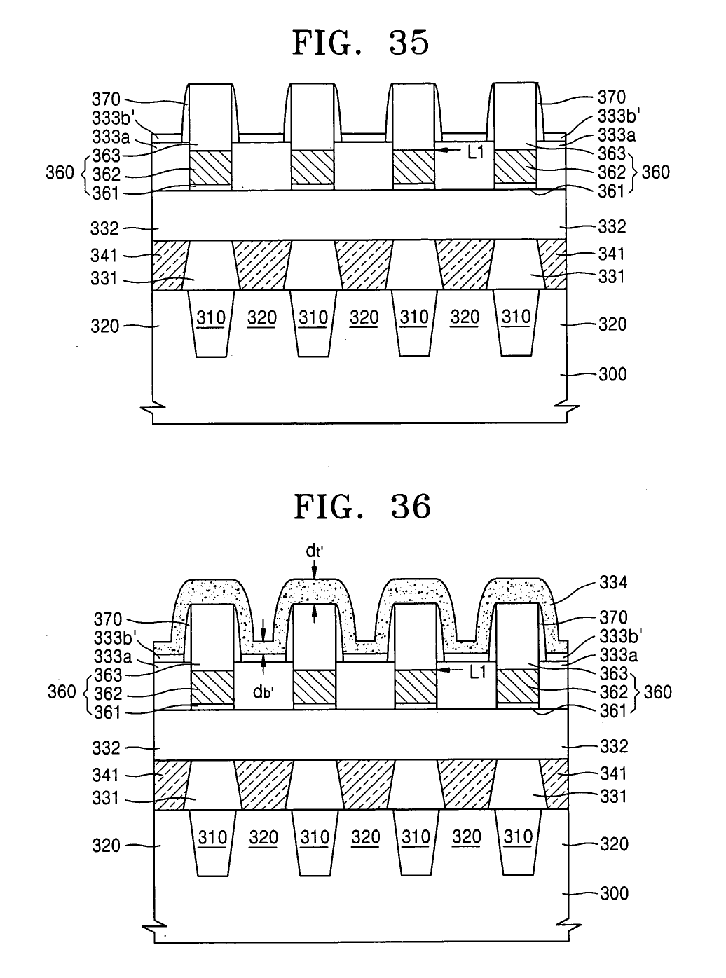

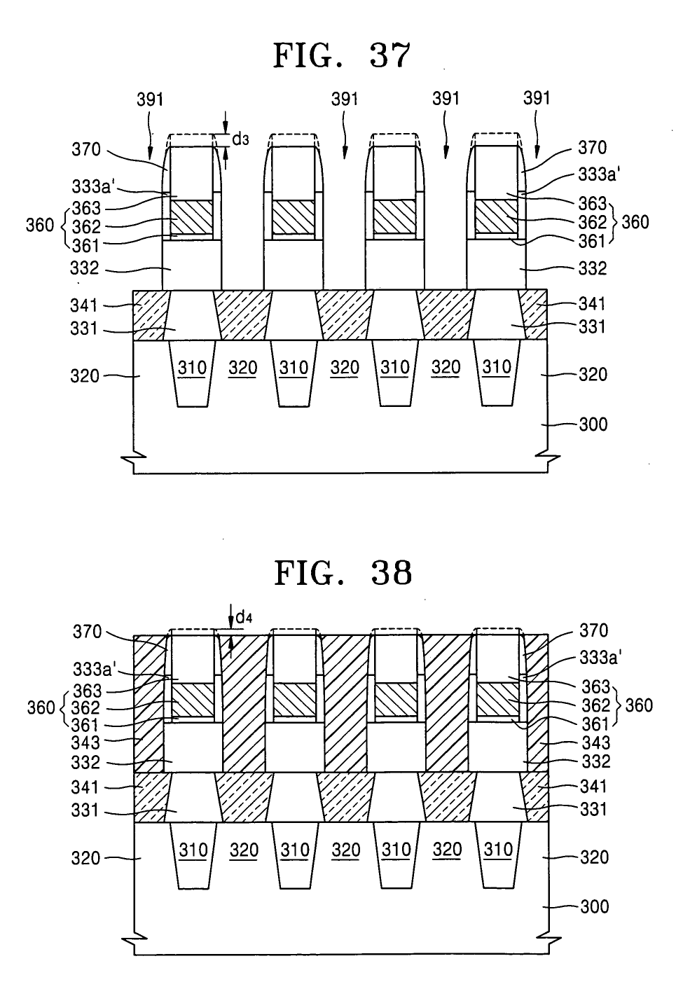

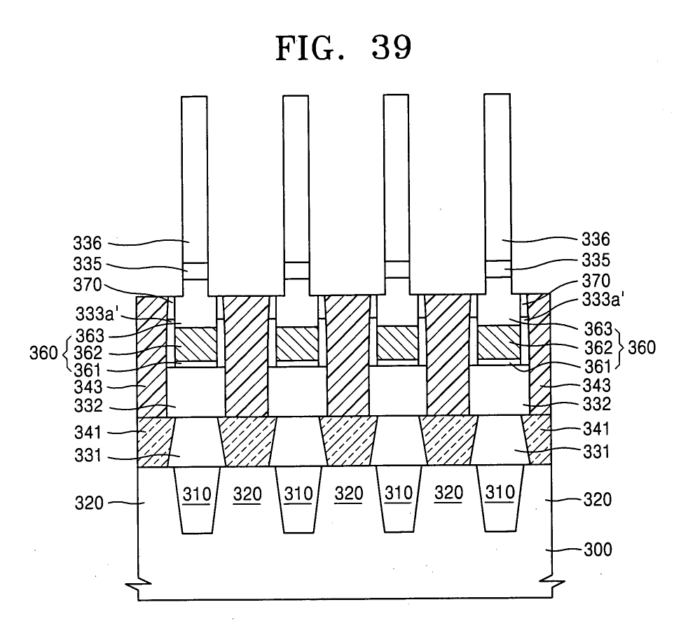

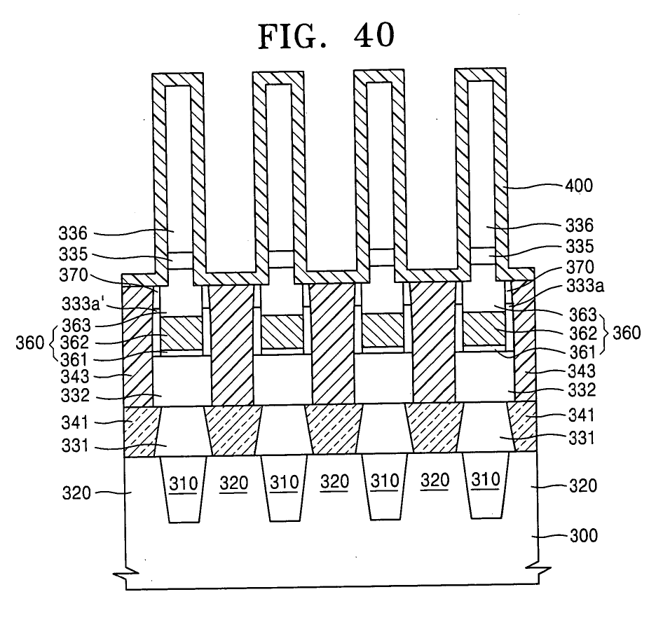

Referring to FIG. 27, a conductive material layer is formed to completely fill the BC contact holes 391. Next, an etching process is performed to separate BC contact plugs 343. In some cases, a planarization process may be performed after the etching process. The etching process is an over-etching process of etching a predetermined thickness d₄ of the upper portions of the mask layers 363 of the bit line stacks 360. The thickness d₄ of the removed portions of the mask layers 363 may be smaller than that of the conventional case (see d1′ of FIG. 8). This is because the thickness of the removed portions of the mask layers 363 due to the etching process on the remaining third insulating layer 333′ and the second insulating layer 332 is relatively small (see d₃ of FIG. 26). As a result, there is not large step deference between the thicknesses of the removed portion of the mask layers 363 and other portions thereof. Therefore, in the embodiment of the present invention, thickness d₄ of the removed portions of the mask layers 363 can be small without any problems.

Referring to FIGS. 16, 28, and 29, an etching stopper layer 335 and a mold oxide layer 336 are sequentially stacked on the BC contact plugs 343 and the bit line stacks 360, as shown in FIG. 28. Next, photoresist layer patterns (not shown) are formed on the mold oxide layer 336 to expose some portions of the surface of the mold oxide layer 336. The exposed portions of the mold oxide layer 336 and the etching stopper layer 335 are removed by performing an etching process using the photoresist layer patterns as etching masks. As a result, contact holes exposing top surfaces of the BC contact plugs 343 are obtained. Although some portions of the mask layers 363 of the bit line stacks 360 are etched during the etching process, since the sufficiently large thickness of the mask layers 363 is previously formed, the thickness of the remaining mask layers 363 is relatively large.

As shown in FIG. 29, lower electrode layer 400 is formed to contact the top surfaces of the BC contact plugs 343 exposed by the aforementioned etching process. Next, although not shown in the figure, a dielectric layer and an upper electrode layer of a capacitor are sequentially formed on the lower electrode layer 400 by using a conventional capacitor forming process.

FIGS. 30 to 40 are cross sectional views for explaining a method of forming self-aligned contacts in a semiconductor memory device and a method of manufacturing a semiconductor memory device using the method of forming the self-aligned contacts according to another embodiment of the present invention.

In an embodiment, since some portions of bit line spacer layers are made of silicon oxide of which the dielectric constant is lower than that of silicon nitride, a bit line loading capacitance C_{BL} can be reduced. More specifically, the bit line loading capacitance C_{BL} is represented by Equation 1.

$${C}_{BL} = \frac{ɛ \times A}{t} \qquad [ Equation 1 ]$$

Here, ε, A, and t are a dielectric constant, a contacting area, and a thickness of a dielectric layer, respectively.

As can be understood in Equation 1, the bit line loading capacitance C_{BL} is proportional to the dielectric constant ε. As the dielectric constant ε of the dielectric layer between the bit line stacks becomes small, the bit line loading capacitance C_{BL} decreases. In the present embodiment, since the lower portions of the bit line spacer layers are made of silicon oxide rather than silicon nitride, the bit line loading capacitance C_{BL} can be reduced.

FIGS. 30 and 31 are cross sectional views taken along lines A-A′ and B-B′ of FIG. 14, respectively. FIGS. 32 is a cross sectional view taken along a line B-B′ of FIG. 15. FIGS. 33 and 34 are cross sectional views taken along lines A-A′ and B-B′ of FIG. 15, respectively. FIGS. 35 to 38 are cross sectional views taken along lines A-A′ of FIG. 15. FIGS. 39 and 40 are cross sectional views taken along lines A-A′ of FIG. 16.

Referring to FIGS. 10 to 12, 30 and 31, an isolation layer 310 is formed on a semiconductor substrate 300 to define active regions 320 where devices are formed. Next, gate stacks 350 are formed on the semiconductor substrate 300. The gate stacks 350 extend in a stripe across a row of active regions 320, as shown in FIG. 12. After the gate stacks 350 are formed, gate spacer layers (not shown) are formed on the side surfaces of the gate stacks 350. Next, conductive pads 341 and 342 are formed to pass through a first insulating layer 331 between the gate stacks 350. The conductive pads 341 are BC pads 341 for connecting the active regions 320 to lower electrodes of capacitors, and the conductive pads 342 are DC pads 342 for connecting the active regions 320 to bit lines. Next, a second insulating layer 332 is formed on the gate stacks 350 and the conductive pads 341 and 342. Some portions of the second insulating layer 332 are removed by performing an etching process using predetermined mask layer patterns as etching masks to form contact holes exposing only the DC pads 342 out of the conductive pads 341 and 342. Next, DC contact plugs 344 filling the contact holes with a conductive material are formed to contact the DC pads 342.

Next, bit line stacks 360 are formed on the semiconductor substrate 300 in which the second insulating layer 332 and the DC contact plugs 344 are formed. The bit line stacks 360 extend in the longitudinal direction as stripes to intersect the gate stacks 350. Each of the bit line stacks 360 are formed by sequentially stacking a barrier layer 361, a metal layer 362, and a mask layer 363. Typically, the mask layers 363 are made of silicon nitride SiN.

Next, a lower third insulating layer 333a constituting a portion of the third insulating layer 333 is formed on the second insulating layer 332. The level of the top surface of the lower third insulating layer 333a is arranged to be higher than the level of the top surfaces of the metal layers 362 of the bit line stacks 360. The lower third insulating layer 333a is an oxide layer formed by using a CVD method or a high-density plasma (HDP) deposition method. Next, bit line spacer layers 370 are formed on sidewalls of the bit line stacks 360 by performing a sidewall spacer forming process. Next, gaps between the bit line stacks 360 are filled with an upper third insulating layer 333b constituting a portion of the third insulating layer 333. As a result, the third insulating layer 333 has a stacked structure of the lower third insulating layer 333a and the upper third insulating layer 333b.

Referring to FIG. 15 and 32, photoresist layer patterns 382 are formed as mask layer patterns on the bit line stacks 360 and the third insulating layer 333. The photoresist layer patterns 382 extend in the longitudinal direction as stripes, so that the photoresist layer patterns 382 intersect the bit line stacks 360 and partially overlap the gate stacks 350 in parallel. In particular, the photoresist layer patterns 382 have openings covering the DC contact plugs 344 and exposing some portions of the third insulating layer 333 where the BC pads 341 are formed. A structure shown on the cross section taken along the line A-A′ of FIG. 15 is the same as the structure shown in the cross section view of FIG. 30.

Alternatively, as shown in FIGS. 33 and 34, conductive layers 381 made of polysilicon may first be formed. The photoresist layer patterns 382 are formed as mask layer patterns on the conductive layers 381. In this case, after the conductive layers 381 and the photoresist layer patterns 382 are sequentially stacked, a photoresist layer is patterned to cover the DC contact plugs 344 and expose some portions of the third insulating layer 333 where the BC pads 341 are formed.

Referring to FIG. 35, the exposed portions of the upper third insulating layer 333b are removed by performing an etching process.

First, description is made about the aforementioned case where the conductive layers 381 are not formed. By performing the etching process using the photoresist layer patterns 382 as the etching masks, the exposed portions of the upper third insulating layer 333b are removed by a predetermined thickness. Here, the level of top surface of the remaining upper third insulating layer 333b is arranged to be higher than at least the level L1 of the top surfaces of the metal layers 362 of the bit line stacks 360.

Next, description is made about the aforementioned alternative case where the conductive layers 381 are formed. By performing the etching process using the photoresist layer patterns 382 as the etching masks, all the exposed portions of the conductive layers 381 are removed. As a result, conductive layer patterns 381 are formed under the photoresist layer patterns 382. Next, the photoresist layer patterns 382 are removed, so that the conductive layer patterns 381 are exposed. Next, some portions of the upper third insulating layer 333b are removed by performing an etching process using the conductive layer patterns 381 as etching masks. In both cases, since the etching process is performed to remove only the predetermined thickness of the upper third insulating layer 333b, it is possible to perform the etching process with a sufficiently high etching selection ratio in comparison with a conventional etching process.

Referring to FIG. 36, after some portions of the upper third insulating layer 333b are removed, a capping spacer layer 334 is formed on the remaining upper third insulating layer 333b, the bit line stacks 360, and the bit line spacer layers 370. The capping spacer layer 334 is made of, for example, silicon oxide which has low step coverage by using a CVD method. As a result, the thickness d_{b} of the capping spacer layer 334 over the upper third insulating layer 333b is thicker than the thickness dₜ of the capping spacer layer 334 over the bit line stacks 360.

Referring to FIG. 37, a dry etching process is performed on the entire surface of the resulting product, in which the capping spacer layer 334 is formed, to sequentially remove the capping spacer layer 334, the remaining upper third insulating layer 333b, the lower third insulating layer 333a, and the exposed portions of the second insulating layer 332. Here, the dry etching process is performed with a relatively low etching selection ratio in comparison with the etching process of removing some portions of the upper third insulating layer 333b. As a result of the dry etching process, BC contact holes 391 exposing top surfaces of the BC pads 341 are obtained, and at the same time, the remaining lower third insulating layer 333a′ is formed on the sidewalls of the bit line stacks 360. The remaining lower third insulating layer 333a′ together with the bit line spacer layer 370 has a function of a sidewall spacer layer of each of the bit lines. The thickness of the remaining lower third insulating layer 333a′ can be adjusted by using the thickness of the capping insulating layer 334.

During the dry etching process, the capping spacer layer 334 on mask layers 363 of the bit line stacks 360 has a function of a buffer for the mask layers 363. Therefore, the thickness d₃ of the etched portions of the mask layers 363 is not large. In addition, the capping spacer layer 334 on the bit line spacer layers 370 has a function of a buffer for the bit line spacer layers 370, so that the reduction of the thickness of the bit line spacer layers 370 can be suppressed during the dry etching process.

Referring to FIG. 38, a conductive material layer is formed to completely fill the BC contact holes 391. Next, an etching process is performed to separate BC contact plugs 343. In some cases, a planarization process may be performed after the etching process. The etching process is an over-etching process of etching a predetermined thickness d₄ of the upper portions of the mask layers 363 of the bit line stacks 360. The thickness d₄ of the removed portions of the mask layers 363 may be smaller than that of the conventional case (see d₁′ of FIG. 8). This is because the thickness of the removed portions of the mask layers 363 due to the etching process on the remaining upper third insulating layer 333b, the lower third insulating layer 333a, and the second insulating layer 332 is relatively small (see d₃ of FIG. 37). As a result, there is not a large step difference between the thicknesses of the removed portion of the mask layers 363 and other portions thereof. Therefore, in the embodiment of the present invention, thickness d₄ of the removed portions of the mask layers 363 can be small without any problems.

Referring to FIGS. 16 and 39, an etching stopper layer 335 and a mold oxide layer 336 are sequentially stacked on the BC contact plugs 343 and the bit line stacks 360 as shown in FIG. 39. Next, photoresist layer patterns (not shown) are formed on the mold oxide layer 336 to expose some portions of the surface of the mold oxide layer 336. The exposed portions of the mold oxide layer 336 and the etching stopper layer 335 are removed by performing an etching process using the photoresist layer patterns as etching masks. As a result, contact holes exposing top surfaces of the BC contact plugs 343 are obtained. Although some portions of the mask layers 363 of the bit line stacks 360 are etched during the etching process, since the sufficiently large thickness of the mask layers 363 is previously formed, the thickness of the remaining mask layers 363 is relatively large.

As shown in FIG. 40, a lower electrode layer 400 is formed to contact the top surfaces of the BC contact plugs 343 exposed by the aforementioned etching process. Next, although not shown in the figure, a dielectric layer and an upper electrode layer of a capacitor are sequentially formed on the lower electrode layer 400 by using a conventional capacitor forming process.

According to a method of forming a self-aligned contact and a method of manufacturing a semiconductor memory device by using the method of the self-aligned contact of the embodiments of the present invention, some portions of interlayer insulating layers are firstly removed to form contact holes for buried contact (BC) plugs, a capping insulating layer is formed to cover bit line stacks, and then etching processes are formed to remove exposed portions of the capping insulating layer and the interlayer insulating layers. Since the capping insulating layer has a function of a buffer, an etched amount of mask layers masking conductive layers of the bit line stacks is minimized. Therefore, it is possible to effectively reduce a probability of a short circuit occurring between a lower electrode layer of a capacitor and a conductive layer of the bit line stack in the process. In addition, since lower portions of the sidewall spacer layers formed on sidewalls of the bit line stacks are made of a dielectric material having a relatively low dielectric constant, it is possible to reduce a bit line loading capacitance.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of forming a semiconductor memory device, the method comprising:
stacking a conductive layer and an insulating mask layer to form conductive stacks on a semiconductor substrate;
forming insulating spacer layers on sidewalls of the conductive stacks;
forming an insulating layer to fill gaps between the conductive stacks;
forming mask layer patterns to expose first portions of the insulating layer;
removing the exposed first portions of the insulating layer;
forming a capping insulating layer covering second portions of the insulating layer, the insulating spacer layers, and the conductive stacks;
forming contact holes to expose portions of the semiconductor substrate by sequentially removing exposed portions of the capping insulating layer and the second portions of the insulating layer; and
forming conductive pads to fill the contact holes to contact the semiconductor substrate.

2. A method of forming a semiconductor memory device, the method comprising:
forming bit line stacks on a lower insulating layer that covers conductive pads;
forming bit line spacer layers on sidewalls of the bit line stacks;
forming an upper insulating layer to fill gaps between the bit line spacer layers;
forming a mask layer pattern to expose first portions of the upper insulating layer;
removing the exposed portions of the upper insulating layer so that a predetermined thickness of the upper insulating layer remains over the lower insulating layer;
forming a capping insulating layer to cover second portions of the upper insulating layer, the bit line spacer layers, and the bit line stacks;
sequentially removing exposed portions of the capping insulating layer, the second upper insulating layer, and the lower insulating layer to form contact holes that expose the conductive pads; and
forming conductive plugs that fill the contact holes to contact the conductive pads.

3. The method according to claim 2, wherein each of the bit line stacks is formed by sequentially stacking a barrier layer, a conductive layer, and a mask layer.

4. The method according to claim 3, wherein a top surface of the remaining upper insulating layer is higher than a top surface of the conductive layer of the bit line stack.

5. The method according to claim 2, wherein the capping insulating layer is an oxide layer formed by using a chemical vapor deposition process with poor step coverage.

6. The method according to claim 2, wherein the capping insulating layer on the bit line stack is thicker than the capping insulating layer on the upper insulating layer.

7. The method according to claim 2, wherein the capping insulating layer is a silicon nitride layer formed by a physical vapor deposition process with poor step coverage.

8. The method according to claim 2, wherein the capping insulating layer is a silicon nitride layer formed by a low-pressure chemical vapor deposition process.

9. The method according to claim 2, wherein the mask layer pattern is a photoresist layer pattern substantially having a form of a line to expose the first portions of the upper insulating layer.

10. The method according to claim 2, wherein the mask layer pattern is a polysilicon layer pattern having a form of a contact to expose the first portions of the upper insulating layer.

11. The method according to claim 10, wherein the forming of the polysilicon layer pattern as the mask layer pattern comprises:
forming a polysilicon layer on the upper insulating layer and the bit line stack;
forming a photoresist layer pattern having a form of a line on the polysilicon layer to expose portions of the polysilicon layer;
performing an etching process using the photoresist layer pattern as an etching mask to remove the exposed portions of the polysilicon layer; and
removing the photoresist layer pattern to expose the polysilicon layer pattern.

12. A method of forming self-aligned contacts in a semiconductor memory device, comprising:
forming bit line stacks on a lower insulating layer that covers conductive pads;
forming a first upper insulating layer having a predetermined thickness on the lower insulating layer between the bit line stacks;
forming bit line spacer layers on sidewalls of the bit line stacks;
forming a second upper insulating layer on the first upper insulating layer between the bit line spacer layers;
forming a mask layer pattern to expose first portions of the second upper insulating layer,
performing an etching process using the mask layer patterns as etching masks to remove the exposed first portions of the second upper insulating layer;
forming a capping insulating layer to cover second portions of the second upper insulating layer, the bit line spacer layers, and the bit line stacks;
sequentially removing exposed portions of the capping insulating layer, a remaining first upper insulating layer, the second portions of the second upper insulating, and the lower insulating layer to form contact holes that expose the conductive pads; and
forming conductive plugs that fill the contact holes to contact the conductive pads.

13. The method according to claim 12, wherein the first upper insulating layer is a dielectric layer having a lower dielectric constant than that of the bit line spacer layers.

14. The method according to claim 12, wherein each of the bit line stacks is formed by sequentially stacking a barrier layer, a conductive layer, and a mask layer.

15. The method according to claim 14, wherein as a result of the etching process performed on the second upper insulating layer, a top surface of the remaining second upper insulating layer is higher than a top surface of the conductive layer of the bit line stack.

16. The method according to claim 12, wherein the capping insulating layer is an oxide layer formed by using a chemical vapor deposition process with poor step coverage.

17. The method according to claim 12, wherein the capping insulating layer on the bit line stack is thicker than the capping insulating layer on the second upper insulating layer.

18. The method according to claim 12, wherein the capping insulating layer is a silicon nitride layer formed by a physical vapor deposition process with poor step coverage.

19. The method according to claim 12, wherein the capping insulating layer is a silicon nitride layer formed by a low-pressure chemical vapor deposition process.

20. The method according to claim 12, wherein the mask layer pattern is a photoresist layer pattern substantially having a form of a line to expose the first portions of the second upper insulating layer.

21. The method according to claim 12, wherein the mask layer pattern is a polysilicon layer pattern having a form of a contact to expose some portions of the insulating layer.

22. The method according to claim 21, wherein the forming of the polysilicon layer pattern as the mask layer pattern comprises:
forming a polysilicon layer on the second upper insulating layer and the bit line stack;
forming a photoresist layer pattern having a form of a line on the polysilicon layer to expose portions of the polysilicon layer;
performing an etching process using the photoresist layer pattern as an etching mask to remove the exposed portions of the polysilicon layer; and
removing the photoresist layer pattern to expose the polysilicon layer pattern.

23. A method of manufacturing a semiconductor memory device, the method comprising:
forming conductive pads passing through a first insulating layer on a semiconductor substrate to be connected to active regions defined in the semiconductor substrate;
forming a second insulating layer on the first insulating layer and the conductive pads;
forming bit line stacks on the second insulating layer;
forming bit line spacer layers on sidewalls of the bit line stacks;
forming a third insulating layer to fill gaps between the bit line spacer layers;
forming mask layer patterns to expose first portions of the third insulating layer;
performing an etching process using the mask layer patterns as etching masks to remove the exposed first portions of the third insulating layer so that a predetermined thickness of the third insulating layer remains over the second insulating layer;
forming a capping insulating layer to cover second portions of the third insulating layer, the bit line spacer layers, and the bit line stacks;
sequentially removing exposed portions of the capping insulating layer, the second portions of the third insulating layer, and the second insulating layer to form contact holes that expose the conductive pads;
forming conductive plugs that fill the contact holes to contact the conductive pads;
sequentially forming an etching stopper layer and a mold oxide layer on the conductive plugs and the bit line stacks;
patterning the etching stopper layer and the mold oxide layer to form contact holes to expose the conductive plugs;
forming a lower electrode layer used for a low electrode of a capacitor on the conductive plugs, the etching stopper layer, and the mold oxide layer; and
forming a dielectric layer and an upper electrode layer on the lower electrode layer.

24. A method of manufacturing a semiconductor memory device, comprising:
forming conductive pads passing through a first insulating layer on a semiconductor substrate to be connected to active regions in the semiconductor substrate;
forming a second insulating layer on the first insulating layer and the conductive pads;
forming bit line stacks on the second insulating layer;
forming a lower third insulating layer on the second insulating layer between the bit line stacks;
forming bit line spacer layers on sidewalls of the bit line stacks;
forming an upper third insulating layer on the lower third insulating layer between the bit line stacks;
forming mask layer patterns to expose first portions of the upper third insulating layer;
performing an etching process using the mask layer patterns as etching masks to remove the exposed first portions of the upper third insulating layer;
forming a capping insulating layer to cover second portions of the upper third insulating layer, the bit line spacer layers, and the bit line stacks;
sequentially removing exposed portions of the capping insulating layer, the second portions of the remaining upper third insulating layer, a remaining lower third insulating layer, and the second insulating layer to form contact holes that expose the conductive pads;
forming conductive plugs that fill the contact holes to contact the conductive pads;
sequentially forming an etching stopper layer and a mold oxide layer on the conductive plugs and the bit line stacks;
patterning the etching stopper layer and the mold oxide layer to form contact holes that expose the conductive plugs;
forming a lower electrode layer used for a low electrode of a capacitor on the conductive plugs, the etching stopper layer, and the mold oxide layer; and
forming a dielectric layer and an upper electrode layer on the lower electrode layer.

25. The method according to claim 24, wherein the lower third insulating layer is formed by using a dielectric material having a lower dielectric constant than that of the bit line spacer layers.

26. A method of manufacturing a semiconductor memory device, comprising:
stacking a conductive layer and an insulating mask layer in this order to form conductive stacks on a semiconductor substrate;
forming insulating spacer layers on sidewalls of the conductive stacks;
forming an insulating layer to fill gaps between the conductive stacks;
forming mask layer patterns to expose first portions of the insulating layer;
performing an etching process using the mask layer patterns as etching masks to remove the exposed first portions of the insulating layer;
forming a capping insulating layer covering second portions of the insulating layer, the insulating spacer layers, and the conductive stacks;
forming contact holes to expose portions of the semiconductor layer by sequentially removing exposed portions of the capping insulating layer and the second portions of the insulating layer; and
forming conductive pads to fill the contact holes to contact the semiconductor substrate.
